(19) United States
(12) Patent Application Publication
(10) Pub. No.: US 2025/0344339 A1
(43) Pub. Date: Nov. 6, 2025

(54) AIR HANDLING UNIT HAVING A HEAT SHIELD FLOW DISTRIBUTOR

(71) Applicant: Carrier Corporation, Palm Beach Gardens, FL (US)

(72) Inventors: Nikhil Dhingra, Indianapolis, IN (US); Dennis Blessing, Bargersville, IN (US); Rade Lukic, Carmel, IN (US); Kiran Kumar Akula, Hyderabad (IN)

(21) Appl. No.: 19/269,438

(22) Filed: Jul. 15, 2025

Related U.S. Application Data
(63) Continuation-in-part of application No. 19/192,535, filed on Apr. 29, 2025.
Application No. 19/192,535 is a continuation-in-part of application No. 18/745,286, filed on Jun. 17, 2024.
(60) Provisional application No. 63/511,199, filed on Jun. 30, 2023.

(51) Int. Cl. H05K 7/20; F24F 13/08; F24F 13/20

(52) U.S. Cl. CPC H05K 7/20136; F24F 13/08; F24F 13/20; F24F 2013/205; F24F 2221/34

(57) ABSTRACT

Described herein is an air handling unit (AHU), comprising a motor-driven fan configured to generate an airflow through a housing, one or more heat elements downstream of the fan to heat the airflow, a control box within the housing containing control electronics to control the heat elements, and a supplementary heat shield between the heat elements and the control box. The supplementary heat shield and control box form a passage for airflow, allowing the control electronics to dissipate thermal losses, and the heat shield reduces heat transfer from the heat elements.

### CROSS-REFERENCE TO RELATED APPLICATION

This application is a Continuation-in-part of U.S. Non-provisional application Ser. No. 19/192,535 filed on Apr. 29, 2025, which in turn is a Continuation-in-part of U.S. Non-provisional application Ser. No. 18/745,286 filed on Jun. 17, 2024, which claims the benefit of U.S. Provisional Patent Application No. 63/511,199, filed on Jun. 30, 2023, which is incorporated by reference herein in its entirety.

### TECHNICAL FIELD

The subject disclosure relates to an air handling unit, and more particularly, to an air handling unit having a heat shield flow distributor.

### BACKGROUND

Ducted residential air handling units (AHUs) for heating, ventilation and air conditioning (HVAC) typically include a primary refrigerant-to-air heat exchanger, a motor-driven blower, refrigerant piping and valves, electronic controls, and optional electric heat. The electric heat may be used as the only source for comfort heating in an air conditioning only system, or it may be used to supplement or coordinate with heat transfer from the primary heat exchanger for a system operating as a heat pump. Traditional systems utilize metallic components in the vicinity of the electric heat elements. In particular, these systems typically use metallic double-inlet forward-curved centrifugal blowers and the electric heat elements are placed in the blower discharge section. Thermal radiation exposure from the electric heat in these systems is compatible with the blower components. These traditional systems tend to be relatively large as a consequence of the blower configuration. Alternative AHUs may incorporate a mixed-flow fan, an axial-flow fan, or an in-line centrifugal fan in a more compact arrangement where the fan rotational axis is substantially parallel with the AHU longitudinal direction. These systems may utilize plastic fan components and may place the fan motor drive in the region of the fan discharge. In these alternative systems, the placement of electric heat at the fan discharge may over-heat the fan components, motor, and controls. Example systems of this type may include a solid heat shield. Additionally, control electronics/modules/elements of the heat elements may also generate losses, and be exposed to radiated heat from the heat elements. Increase in operating temperatures of the control electronics introduces inefficiencies in the AHU.

### SUMMARY

Described herein is an air handling unit (AHU), comprising, a motor-driven fan with an annular outlet configured to generate an airflow through a housing of the AHU, one or more heating elements disposed downstream of the motor-driven fan, the one or more heating elements being configured to transfer heat to the airflow, a control box positioned within the housing, the control box housing control electronics configured to control at least the one or more heating elements, and a supplementary heat shield positioned between the one or more heating elements and the control box, wherein the supplementary heat shield and the control box form a passage therebetween through which the airflow is moved, wherein the control electronics dissipate thermal losses to the airflow moving through the passage, and wherein the supplementary heat shield is configured to reduce heat transfer from the one or more heating elements.

In one or more embodiments, the supplementary heat shield is mounted to a primary heat shield disposed between the one or more heating elements and the control electronics.

In one or more embodiments, the supplementary heat shield is oriented on the primary heat shield such that the passage allows the airflow to be moved in a direction along a longitudinal axis of the housing.

In one or more embodiments, the primary heat shield extends across an internal cross-sectional profile of the housing.

In one or more embodiments, the supplementary heat shield is mounted perpendicularly on the primary heat shield.

In one or more embodiments, the supplementary heat shield is mounted downstream of the primary heat shield.

In one or more embodiments, the supplementary heat shield is placed at a distance of _ cm/mm from the control box.

In one or more embodiments, the passage directs at least a portion of the airflow generated by the motor-driven fan to pass between the supplementary heat shield and the control box.

In one or more embodiments, the supplementary heat shield is metallic in construction.

In one or more embodiments, the supplementary heat shield is planar.

In one or more embodiments, the control electronics comprise current modulation devices for controlling power to the one or more heating elements.

In one or more embodiments, the supplementary heat shield is configured to fractionally block, reflect, absorb, and/or radiate the heat from the one or more heating elements to the airflow away from the control box moving downstream from the motor-driven fan.

In one or more embodiments, the control box comprises a back plate configured to dissipate the thermal losses from the control electronics attached thereto to the back plate to the airflow passing through the passage.

In one or more embodiments, the control box comprises one or more heat sinks protruding into the airflow, the one or more heat sinks being configured to dissipate the thermal losses from the control electronics to the airflow through the back plate.

In one or more embodiments, the one or more heat sinks are disposed upstream of the supplementary heat shield.

In one or more embodiments, the AHU further comprises a primary heat exchanger configured to cool or heat the airflow passing through the AHU.

In one or more embodiments, the control box is positioned downstream of the motor-driven fan, on a side wall of the housing.

Described herein is an air handling unit (AHU), comprising, a motor-driven fan with an annular outlet configured to generate an airflow through a housing of the AHU, one or more heating elements disposed downstream of the motor-driven fan, the one or more heating elements being configured to transfer heat to the airflow, a control box positioned within the housing, the control box housing control electronics configured to control at least the one or more heating elements, and an supplementary heat shield attached to the control box, wherein the supplementary heat shield is configured to dissipate heat from the control electronics to the airflow, and wherein the supplementary heat shield is configured to reduce heat transfer from the one or more heating elements.

The foregoing summary is illustrative only and is not intended to be in any way limiting. In addition to the illustrative aspects, embodiments, and features described above, further aspects, embodiments, features, and techniques of the invention will become more apparent from the following description taken in conjunction with the drawings.

### BRIEF DESCRIPTION OF THE DRAWINGS

The accompanying drawings are included to provide a further understanding of the subject disclosure of this invention and are incorporated in and constitute a part of this specification. The drawings illustrate exemplary embodiments of the subject disclosure and, together with the description, serve to explain the principles of the subject disclosure.

In the drawings, similar components and/or features may have the same reference label. Further, various components of the same type may be distinguished by following the reference label with a second label that distinguishes among the similar components. If only the first reference label is used in the specification, the description is applicable to any one of the similar components having the same first reference label irrespective of the second reference label.

FIG. 1A is a cross-sectional representation of a side view of an air handling unit (AHU), in accordance with one or more embodiments of the subject disclosure.

FIG. 1B is a cross-sectional representation of an end or front view of the AHU, in accordance with one or more embodiments of the subject disclosure.

FIG. 2A is a cross-sectional representation of the side of the AHU shown in FIG. 1A, with paths of airflow through the AHU, in accordance with one or more embodiments of the subject disclosure.

FIG. 2B is an enlarged representation of the airflow through the AHU of FIG. 2A, in accordance with one or more embodiments of the subject disclosure.

FIG. 2C is a cross-sectional representation of the end or front of the AHU, with paths of the airflow through the AHU, in accordance with one or more embodiments of the subject disclosure.

FIG. 2D is an enlarged representation of the airflow through the AHU of FIG. 2C, in accordance with one or more embodiments of the subject disclosure.

FIG. 2E is an enlarged representation of a slot on the AHU through which at least a portion of the airflow passes, in accordance with one or more embodiments of the subject disclosure.

FIG. 2F is a top view of the AHU having a supplementary heat shield, in accordance with one or more embodiments of the subject disclosure.

FIG. 2G is an orthogonal view of the supplementary heat shield and the heating elements, in accordance with one or more embodiments of the subject disclosure.

FIG. 2H is an enlarged representation of a slot on the AHU formed between a control box and the supplementary heat shield, in accordance with one or more embodiments of the subject disclosure.

FIG. 3A is a cross-sectional representation of the AHU having a planar heat shield, in accordance with one or more embodiments of the subject disclosure.

FIG. 3B is a cross-sectional representation of the AHU having a corrugated heat shield, in accordance with one or more embodiments of the subject disclosure.

FIG. 4A is an isometric view of one or more heat elements of the AHU placed over a planar heat shield, in accordance with one or more embodiments of the subject disclosure.

FIG. 4B is an isometric view of the heat elements of the AHU placed over a corrugated heat shield, in accordance with one or more embodiments of the subject disclosure.

FIGS. 5A to 5D are representations of distribution of openings defined on the heat shield, in accordance with one or more embodiments of the subject disclosure.

FIGS. 6A to 6C are top view representations of different heat shields blocking a line of sight from the heat elements to a motor-driven fan of the AHU, in accordance with one or more embodiments of the subject disclosure.

### DETAILED DESCRIPTION

The following is a detailed description of embodiments of the disclosure depicted in the accompanying drawings. The embodiments are in such detail as to clearly communicate the disclosure. However, the amount of detail offered is not intended to limit the anticipated variations of embodiments; on the contrary, the intention is to cover all modifications, equivalents, and alternatives falling within the spirit and scope of the subject disclosure as defined by the appended claims.

Various terms are used herein. To the extent a term used in a claim is not defined below, it should be given the broadest definition persons in the pertinent art have given that term as reflected in printed publications and issued patents at the time of filing.

In the specification, reference may be made to the spatial relationships between various components and to the spatial orientation of various aspects of components as the devices are depicted in the attached drawings. However, as will be recognized by those skilled in the art after a complete reading of the subject disclosure, the components of this invention described herein may be positioned in any desired orientation. Thus, the use of terms such as “above,” “below,” “upper,” “lower,” “first,” “second,” or other like terms to describe a spatial relationship between various components or to describe the spatial orientation of aspects of such components should be understood to describe a relative relationship between the components or a spatial orientation of aspects of such components.

As used herein, “substantially” means largely or considerably, but not necessarily wholly, or sufficiently to work for the intended purpose. The term “substantially” thus allows for minor, insignificant variations from an absolute or perfect state, dimension, measurement, result, or the like as would be expected by a person of ordinary skill in the art, but that do not appreciably affect overall performance.

The use of the term “about” with reference to a numerical value includes ±10% of the numerical value.

Ducted residential heating, ventilation, and air conditioning (HVAC) systems utilize an air handling unit (AHU) with optional electrically powered heat elements for comfort heating of the air delivered by the AHU. However, such heat elements also radiate heat towards internal components of the AHU, such as fans/blowers, motors, control electronics/modules/circuitry, and the like, potentially causing them to overheat. Overheating such AHU components can lead to inefficiencies and/or risk of damage. These problems are exacerbated in compact, ducted fan coil AHUs where components are placed in close proximity to the heat elements. While some solutions use solid heat shields to protect the AHU components from the heat generated by the heat elements, such heat shields block/impede the flow/redistribution of air through the AHU, thereby leading to inefficiencies. Furthermore, control electronics, such as those that control/operate the heat elements for generating heat, also generate losses, which need to be dissipated.

The subject disclosure solves these problems by providing an AHU with a heat shield having a distribution of openings. The openings allow the air to pass through and be redistributed, while solid portions of the heat shield block radiation, absorb radiation, convect heat to the air stream, and/or reflect radiated energy. Additionally, the subject disclosure provides an AHU with a supplementary heat shield positioned between heat elements and a control box of the AHU. The supplementary heat shield and the control box form a passage for the airflow, to which the control electronics dissipate thermal losses, and wherein the supplementary heat shield is configured to reduce heat transfer from the one or more heat elements.

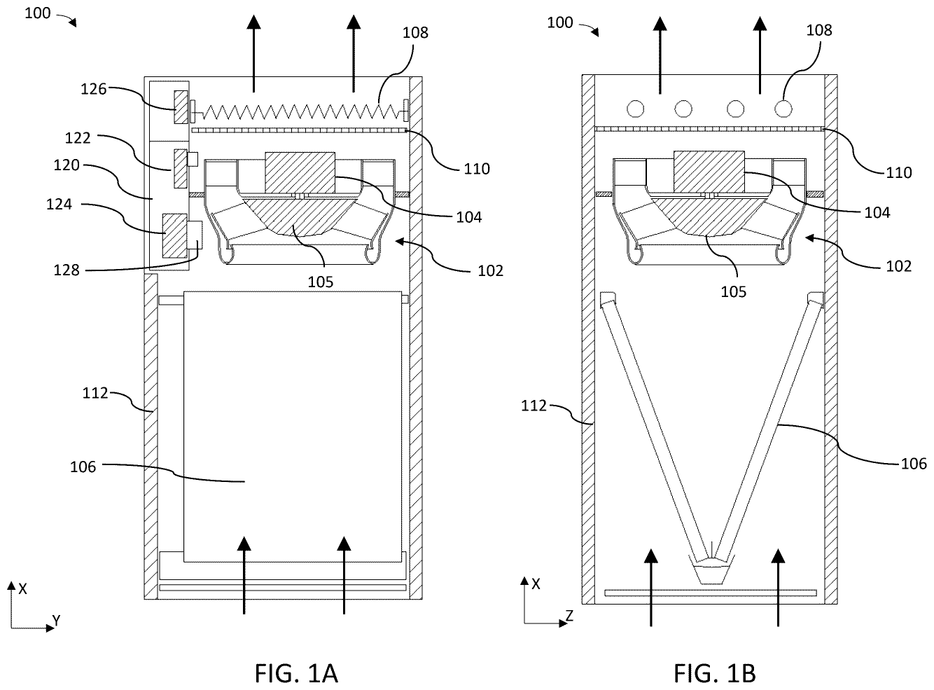

Referring to FIGS. 1A and 1B, cross-sectional representations of a side and an end/front view of an air handling unit (AHU) 100 are shown, respectively. The AHU 100 may include a fan 102, a motor 104, and a primary heat exchanger 106, which may be placed/disposed within a housing duct or a housing 112. The fan 102 (when driven by the motor 104) may be configured to move air through the housing 112. The primary heat exchanger 106 may be configured to cool or heat the air being moved. The AHU 100 may further include one or more heat elements 108 configured to transfer heat to the airflow (i.e., the air being moved through the housing 112). The primary heat exchanger 106 may be placed upstream of the fan 102, and the heat elements 108 may be placed downstream of the fan 102, with respect to the direction in which the air is being moved. To prevent the heat from the heat elements 108 from transferring or propagating to the fan 102 (and other components upstream of the heat elements 108), the AHU 100 may include a heat shield 110. The heat shield 110 may be disposed between the fan 102 and the heat elements 108.

Further, the AHU 100 may include a control box 120 configured to accommodate electrical control modules such as an AHU control module 122, a fan motor power control module 124, and/or a heat control module 126. The fan motor power control module 124 and the heat control module 126 may be configured to control the motor 104, and the heat elements 108, respectively, and the AHU control module 122 may be configured to control the overall operation of the AHU 100. In one or more embodiments, the control box 120 may be positioned downstream of the motor-driven fan 102, on a side wall of the housing 112.

In one or more embodiments, the fan 102 may be configured to move air through the housing 112 of the AHU 100. The fan 102 may be configured to move air in a direction along a longitudinal axis of the housing 112 (such as along X axis with respect to FIGS. 1A to 3B). Solid arrows in FIGS. 1A and 1B represent the air entering and exiting the housing 112. As applied, the AHU housing 112 is nominally connected to return and supply air ducts at the housing inlet and exit, respectively. The main flow through the housing 112 moves in the X direction with respect to FIGS. 1A to 3B), and the fan rotational axis is substantially parallel with the longitudinal axis of the housing 112.

In one or more embodiments, the fan 102 may include any one of a mixed-flow fan/diagonal-flow fan, an axial-flow fan, or a centrifugal fan with rotational axis parallel with a longitudinal direction of the AHU 100. The mixed-flow fan 102 may include a diagonal flow impeller 105 having a plurality of blades extending from the diagonal flow impeller 105, and an axis of rotation of the diagonal flow impeller 105 being arranged in-line with a direction of the airflow through the housing 112.

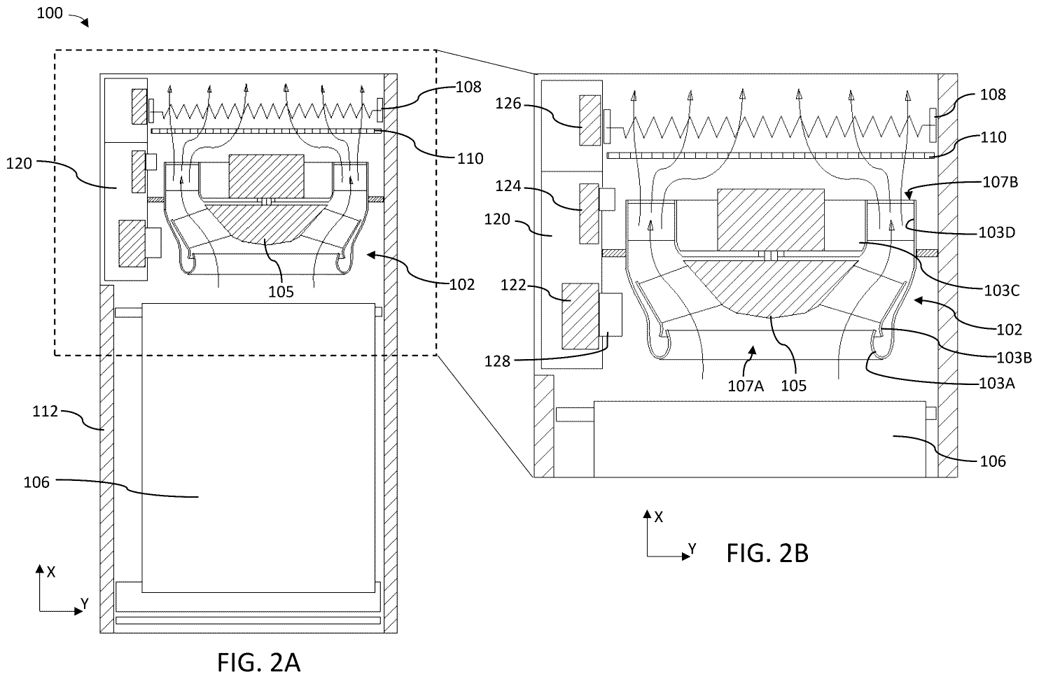

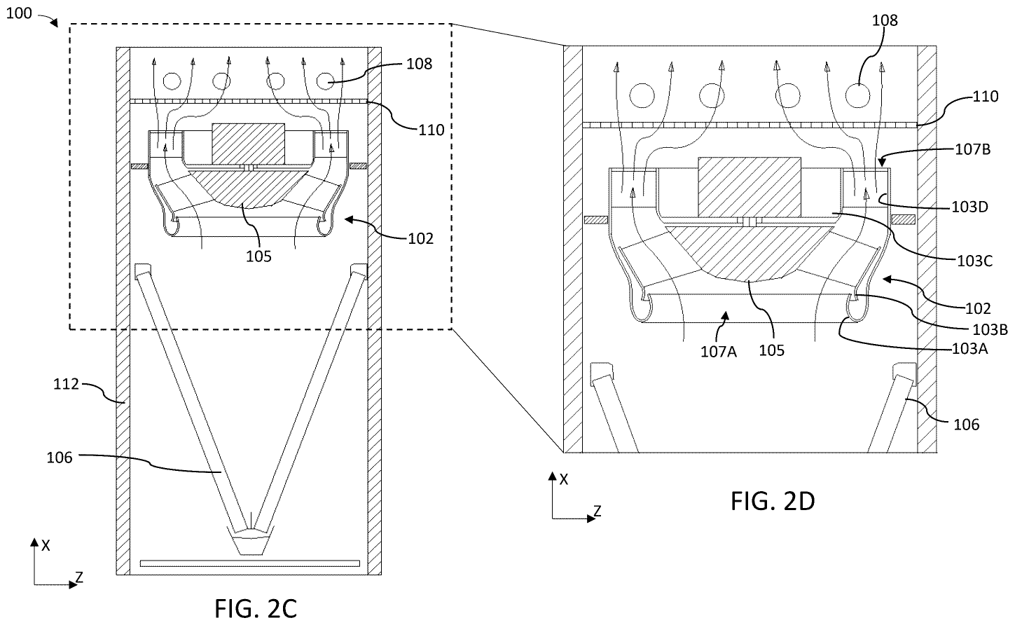

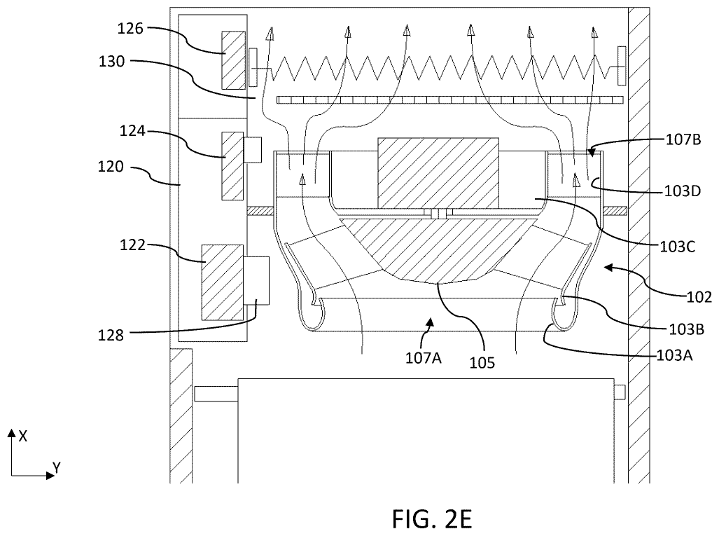

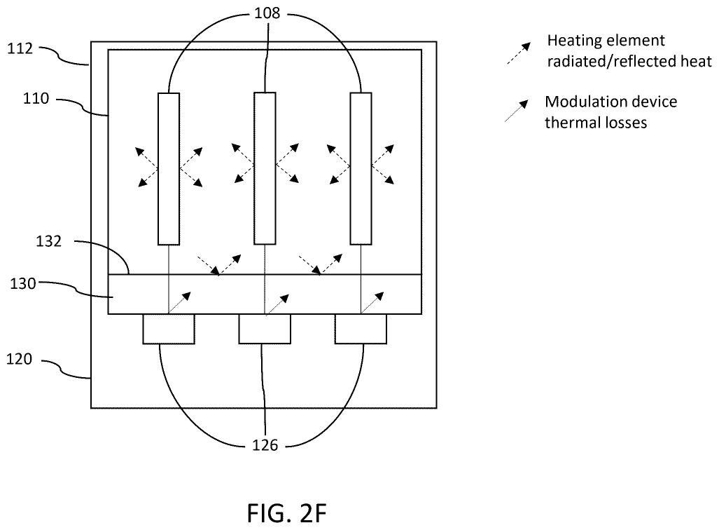

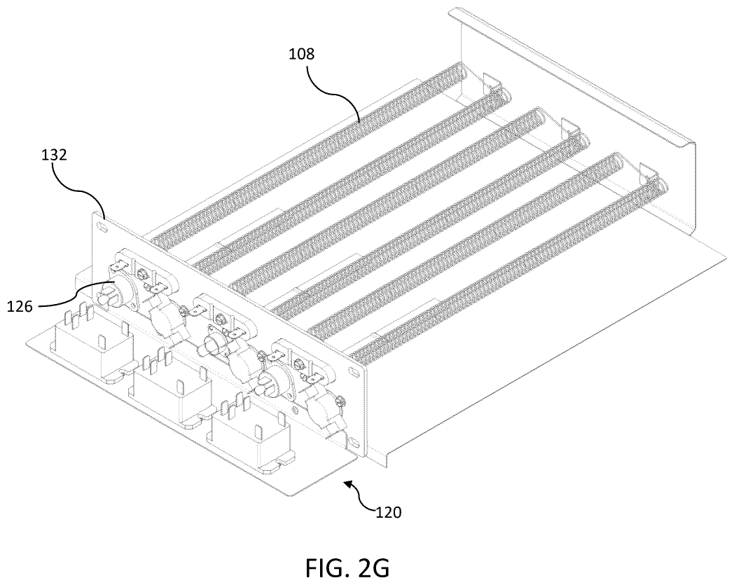

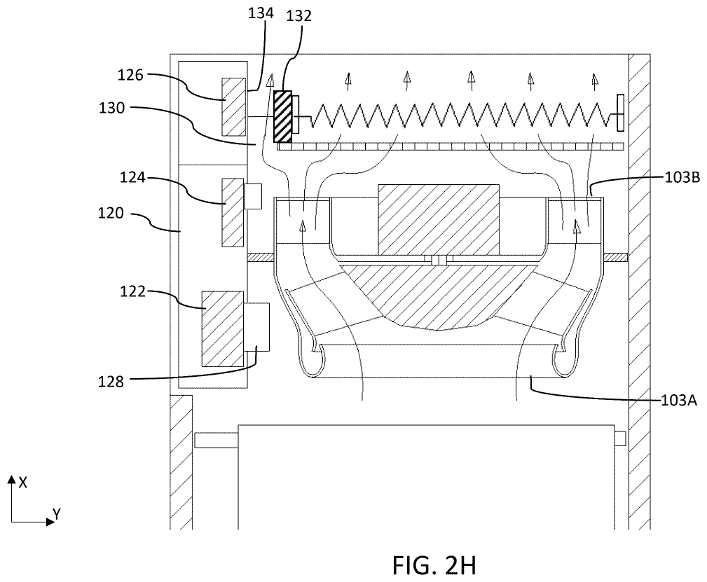

An air flow path (as shown in FIGS. 2A to 2E) through the impeller 105 may be inclined. In one or more embodiments, the air flow path may have a mean angle that is oriented along a direction divergent from the axis of rotation of the impeller 105. The fan 102 may have a fan inlet having a substantially circular shape, and a fan outlet 107B (as shown in FIGS. 2B and 2D) having a substantially annular shape.

The impeller 105 may be driven by a direct-drive motor, such as the motor 104. The direct drive variable speed motor (such as the motor 104) disposed in the stator hub 103C is used to drive the impeller 105 of the fan 102.

The mixed-flow fan also includes a fan inlet casing 103A disposed circumferentially around a shroud wall 103B of the diagonal flow impeller 105 of the fan 102. The fan inlet casing 103A and the shroud wall 103B may define a fan inlet 107A (as shown in FIGS. 2B, 2D, and 2E). Further, a clearance or a gap may be defined between the fan inlet casing 103A and the shroud wall 103B, with upstream and downstream flow control clearances, which may allow for upstream and downstream flow control clearances.

Further, in one or more embodiments, the fan 102 may include a set of outlet guide vanes (not shown) disposed downstream of the impeller 105. The outlet guide vanes may extend radially from a wall of the stator hub 103C towards a stator shroud wall 103D. The guide vanes may be configured to redirect the airflow exiting the impeller 105 such that the airflow exiting the outlet guide vanes is substantially parallel to the axis of rotation of the impeller 105. Such designs of the fan 102 may allow the spatial footprint of the AHU 100 in at least one dimension (such as along the longitudinal axis) to be reduced. Consequently, various components of the AHU 100 may be placed in proximity to each other, including the heat element 108.

In one or more embodiments, the housing 112 may have a substantially rectangular cross-sectional profile. In other embodiments, the housing 112 may have a substantially cylindrical cross-sectional profile.

The fan 102 may be driven by the motor 104. As stated, the motor 104 may be a direct-drive motor. The motor 104 may be operable with a continuous speed control. The motor 104 may be communicably coupled to HVAC controls of the air conditioning unit, or the AHU control module 122.

The motor 104 may have a shaft rotationally locked to the impeller hub/impeller 105 of the fan 102, to allow the motor 104 to drive the fan 102.

In one or more embodiments, the primary heat exchanger 106 may be disposed within the housing 112 of the AHU 100, and positioned along the direction of airflow upstream of the fan 102. In one or more embodiments, the heat exchanger 106 may be configured to facilitate heat transfer to and from the air moving through the housing 112. In some embodiments, the heat exchanger 106 may be configured to cool the air moving through the housing 112. In some other embodiments, the heat exchanger 106 may be configured to heat the air moving through the housing 112.

In one or more embodiments, the primary heat exchanger 106 includes a refrigerant-to-air heat type exchanger. In such embodiments, the primary heat exchanger 106 may include tubing through which a heat exchanging fluid or a refrigerant may be flowed.

The tubing may be routed within one or more heat exchanger slabs. In one or more embodiments, the primary heat exchanger 106 may include two slabs in a substantially V-shaped arrangement, as shown in FIGS. 1B, 2C, 3A and 3B. In other embodiments, the slabs may be arranged substantially A-shaped. In further embodiments, the primary heat exchanger 106 may be a single slab heat exchanger.

In one or more embodiments, the primary heat exchanger 106 may be a microchannel heat exchanger. In one or more embodiments, the primary heat exchanger may be a round-tube plate-fin heat exchanger.

While this disclosure is described in the context of the AHUs having designs similar to that of AHU 100, which allows the components of the AHU 100 to be placed in proximity to each other, it may be appreciated that embodiments of the subject disclosure may be suitably adapted for implementation in other AHU designs, the adaptations being within the scope of the subject disclosure.

In one or more embodiments, the heat elements 108 may be configured to generate heat, and transfer the heat to the airflow. The heat elements 108 may be configured to supplement the heating of the airflow, i.e., in addition to the heating provided by the primary heat exchanger 106, and thereby allow for improved temperature regulation of the airflow. The heat elements 108 may be placed downstream of the fan 102, such that the airflow moved by the fan 102 may be heated by the heat elements 108, before the airflow exits the housing 112.

In one or more embodiments, the heat elements 108 may be electrically powered resistance-type devices implemented as at least one of, coils, strips, ribbons, and/or combined ceramic/metallic construction. In one or more embodiments, the heat elements 108 may extend between at least two walls of the housing 112. In some embodiments, the coils may extend substantially parallel along a plane (such as a plane perpendicular to the longitudinal axis, or a plane formed on by Y and Z axes). Multiple rows of parallel coils may be arranged downstream of the heat shield 110. In other embodiments, heat element coils may be arranged in a concentric circular pattern.

In one or more embodiments, the heat elements 108 may be configured to radiate energy/heat in all directions, including upstream and downstream of the heat elements 108, and also towards the walls of the housing 112. Consequently, the heat from the heat elements 108 may be transferred to the fan 102, the motor 104, the control box 120, and other components of the AHU 100 upstream from the heat elements 108. Such component heating may be undesirable due to its potential to introduce inefficiencies in the operation of, and risk damage to, such components. The AHU 100 may include the heat shield 110 to block or reduce heat transfer from the heat elements 108 to components upstream of the heat shield 110.

In one or more embodiments, the heat shield 110 may be a perforated metallic plate disposed between the fan 102 and the heat elements 108. In one or more embodiments, the heat shield 110 may extend substantially across an internal cross-sectional profile of the housing 112. In such embodiments, the heat shield 110 may be oriented substantially perpendicular to the direction of the airflow, i.e., perpendicular to the longitudinal axis (or the X axis).

In one or more embodiments, the heat shield 110 may be configured to partially block thermal radiation heat transfer from the heat elements 108 to the components upstream of the heat shield 110. Further, the heat shield 110 may also be configured to redistribute the airflow passing therethrough so that the velocity profile becomes more uniform.

In one or more embodiments, the heat shield 110 may be metallic in construction. For instance, the heat shield 110 may include steel or aluminum. The material construction of the heat shield 110 may be selected to withstand the high temperature environment in the vicinity of the heat elements 108.

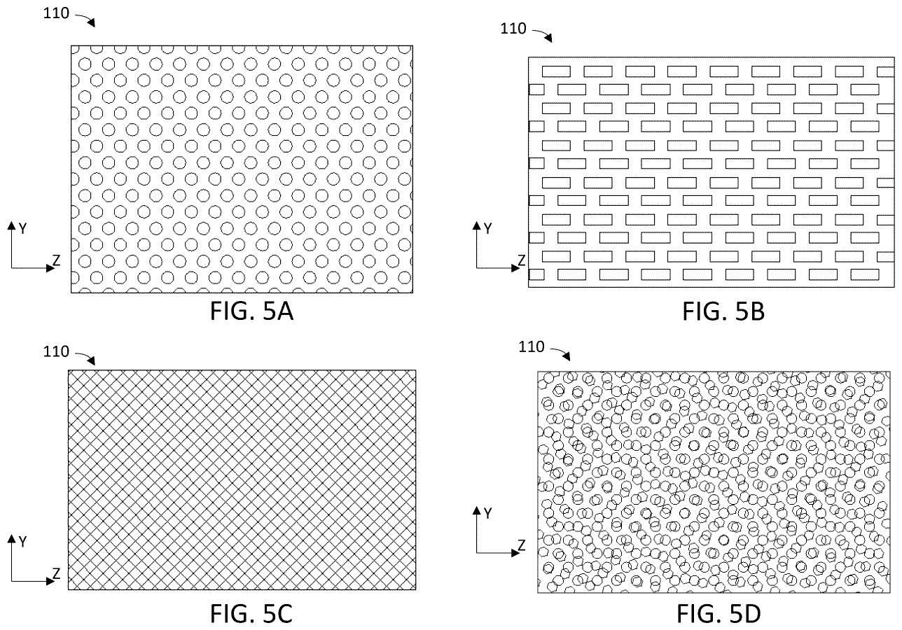

In one or more embodiments, the heat shield 110 may be configured to fractionally block the heat/radiated energy/heat (from the heat elements 108), reflect the radiated energy/heat, absorb the radiated energy/heat, and/or transfer the absorbed energy to the airflow moving downstream from the fan 102 by convection. In one or more embodiments, the heat shield 110 may include a distribution of openings (such as those shown in FIGS. 5A to 5D) defined therein. In one or more embodiments, the openings may be formed by cavities or holes cut out from a solid plate making the heat shield 110.

In other embodiments, the heat shield 110 may be a mesh construction (i.e., woven wire or screen) or made from a set of louvers (which may be arranged or stacked).

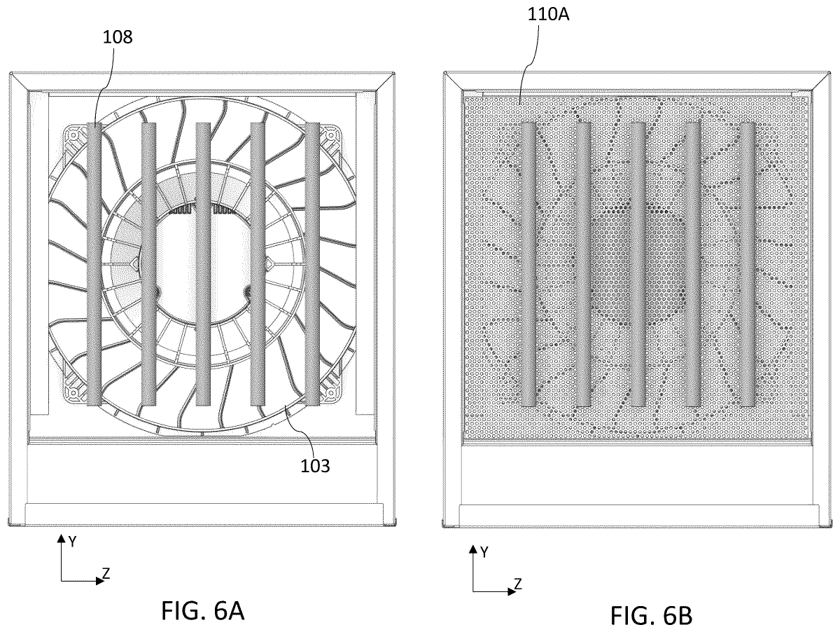

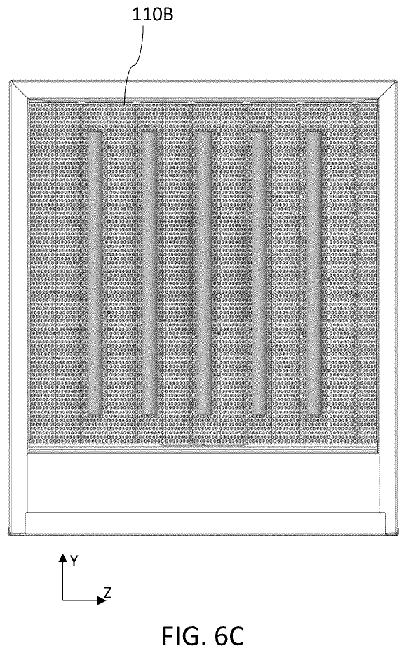

The open cross-sectional area of the perforated plate, mesh, or louvers may be configured to allow the airflow to pass therethrough. In one or more embodiments, the size and shape of the openings may also be adapted to block direct line-of-sight for heat being radiated from the heat elements 108 (as shown in FIGS. 6A to 6C), thereby preventing the heat from propagating to the components upstream of the heat shield 110.

The openings may also be sized, shaped, and/or defined in patterns that facilitate the airflow from the fan 102 to be redistributed when passing through the heat shield 110, i.e., modify the airflow distribution profile downstream of the heat shield 110 so that it becomes more uniform.

In one or more embodiments, the heat shield 110 may be placed at a distance from the fan 102. The distance may be selected to enable the airflow to be distributed as it passes through the heat shield 110. In one or more embodiments, the heat shield 110 may be at a distance of about 5% to about 25% of a fan exit diameter away from the annular outlet 103B of the motor-driven fan 102.

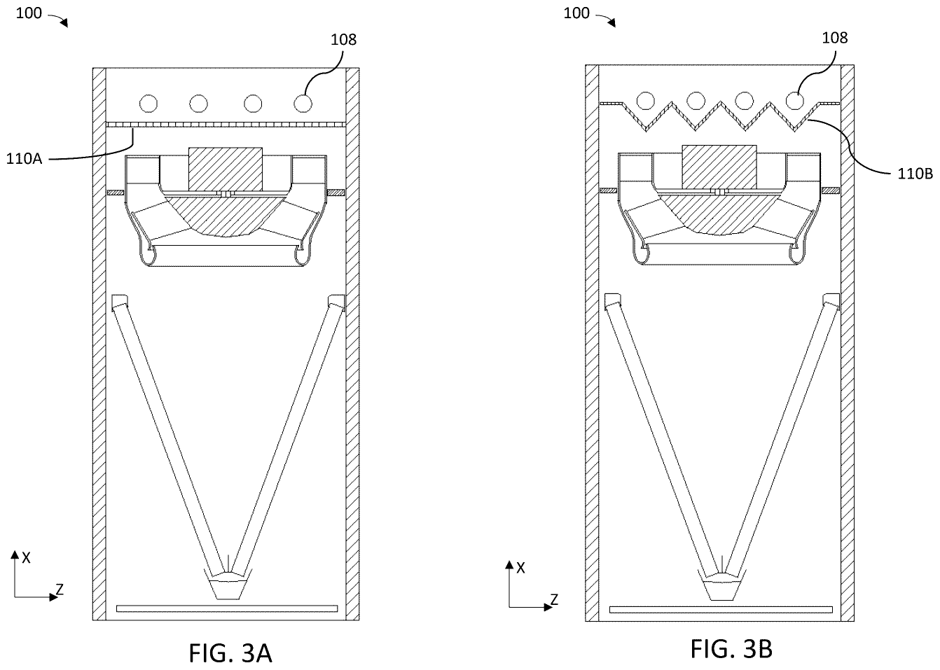

Various designs of the heat shield 110 are provided in FIGS. 3A to 5D, and the ability of the heat shield 110 to block line-of-sight is illustrated in FIGS. 6A to 6C. However, it may be appreciated by those skilled in the art that the heat shield 110 may be implemented with other designs adapted to requirements and/or constraints of the use case, and may not be limited to those shown in the FIGS. 3A to 6C.

Referring to FIGS. 2A to 2D, representations of airflow streamlines are shown. FIG. 2A provides a representation of the side view of the AHU 100, and FIG. 2B shows an enlarged representation thereof, showing airflow streamlines. Similarly, FIG. 2C provides a representation of the front/end view of the AHU 100, and FIG. 2D represents an enlarged representation thereof, also showing airflow streamlines.

In one or more embodiments, the fan 102 may be disposed within the housing 112, to move airflow from an inlet to an outlet of the AHU 100/housing 112, as indicated in FIGS. 1A and 1B using arrows. The fan 102 may be configured to draw air upstream thereof, on being driven by the motor 104 through the fan inlet 107A, which may create a negative pressure upstream of the fan 102. The negative pressure may cause the air to be drawn into the housing 112, either from ambient environment or from other ducts connected to the housing 112. The primary heat exchanger 106, being disposed between the inlet and the fan 102, may exchange heat as the air is moved through housing 112.

The fan 102 may draw the air into the fan inlet 107A, and move the air along the airflow path defined therein. The airflow path within the fan impeller 105 may be inclined with respect to the longitudinal direction.

Further, the fan 102 may discharge the air downstream of the fan 102 through the fan outlet 107B, as shown by arrows in FIGS. 2A to 2D. The fan 102 may be configured to move the air out from the housing 112 through the outlet of the AHU 100. The heat elements 108, being placed between the outlet and the fan 102, may heat the air passing therethrough. The airflow between the inlet and the outlet of the AHU 100 may be substantially parallel to the longitudinal axis (i.e., along X axis) of the housing 112.

As stated, the openings of the heat shield may be shaped and/or sized to redistribute (or change distribution) of the airflow passing through and moving downstream of the heat shield 110. As shown, while the fan outlet 107B may have a substantially annular profile, the openings of the heat shield 110 may cause the distribution of the airflow to change.

The size and shape of the openings may be adjusted to obtain the desired airflow distribution. In one or more embodiments, the openings may be arranged to redistribute the air to be substantially uniform along a cross-sectional area of the AHU 100.

Referring to FIG. 2E, another enlarged representation of the AHU 100 is shown. The control box 120 may be configured to house/accommodate the AHU control module 122, the fan motor power control module 124, and the heat control module 126 (also referred to as control electronics), which may be electronic circuits configured to control the operation of the AHU 100. In one or more embodiments, the control box 120 may be isolated from the housing 112 through-flow moved by the fan 102.

In one or more embodiments, the fan motor power control module 124 may be configured to control the motor 104, i.e., start-up, shut-down, speed control, and the like. The fan motor power control module 124 may transmit control signals to the motor 104, or modulate the amount of electrical power supplied thereto for controlling the motor 104.

In one or more embodiments, each of the heat element 108 may have a corresponding control electronics/heat control module 126. In one or more embodiments, the heat control module(s) 126 may be configured to control the amount of heat generated by the heat elements 108. The heat control module 126 may control the heat elements 108 by modulating the electrical power/electromagnetic energy supplied to the heat elements 108. In one or more embodiments, the heat control module 126 may include current modulation devices for controlling power/electromagnetic energy to the heat elements 108.

In one or more embodiments, the heat control modules 126 may generate thermal losses during the electrical power modulation. Such thermal losses also have to be dissipated to maintain the heat control modules 126 at optimal temperatures. In one or more embodiments, the heat control modules 126 may be positioned on a back plate (such as back plate 134 of FIG. 2H) of the control box 120.

In one or more embodiments, the AHU control module 122 includes a packaged rooftop air management system that is communicably coupled to the different components of the AHU 100, including, without limitations, the heat exchanger 106, the heat elements 108, the fan 102, and the motor 104. The AHU control module 122 may be implemented as a controller configured to control operations of the different components of the AHU 100. Accordingly, the AHU control module 122 may be a master controller, configured to control the fan motor power control module 124 and the heat control module 126 through transmission of electronic signals. In some embodiments, the AHU control module 122 may be a part of the HVAC controls of the air conditioning system.

As stated, the heat radiated from the heat elements 108 may transfer in all directions, including towards the control box 120. Further, heat may also be generated as a result of the operation of the modules within the control box 120. In such cases, the modules within the control box 120 may also heat up, which may cause inefficiencies and/or risk of damage thereto.

In one or more embodiments, corresponding heat sinks (such as heat sink 128) may be disposed/attached to the AHU control module 122, the fan motor power control module 124, and/or heat control modules 126. The heat sinks may be configured to at least partially dissipate heat into the airflow.

In one or more embodiments, the heat sinks may include blocks extending from the corresponding modules. In other embodiments, the heat sinks may include fins through which the heat from the modules may be rejected.

In one or more embodiments, the heat sinks may be made of aluminum. In other embodiments, the heat sinks may be made of any thermally conductive material, which facilitates heat dissipation from the modules within the control box 120 to the airflow.

In one or more embodiments, the heat sinks may be positioned to extend into the airflow path (as indicated by 130 in FIGS. 2E to 2H) within the housing 112. The heat sinks may be configured to dissipate heat from the corresponding modules within the control box 120. In one or more embodiments, the heat sinks may be placed upstream of the heat shield 110. The heat sinks may be configured to dissipate heat to the airflow upstream of the heat shield 110, as shown in FIG. 2E.

In one or more embodiments, the heat/thermal losses generated by the control electronics is dissipated through the air redirected by the distribution of openings of the heat shield 110 or by one or more slots in the heat shield adjacent to the control box 120.

In one or more embodiments, the slots (such as slot 130) may be defined between the control box 120 and the heat shield 110. The slot 130 may be adjacent to the control box 120, to allow at least a portion of the airflow to flow along an end wall of the slot 130. The airflow may absorb heat from the control box 120 when passing through the slot 130.

In such embodiments, the slot 130 may allow the heat in the modules within the control box 120 to be dissipated to the airflow passing through the slot 130.

FIGS. 2F and 2G are top and perspective views of the AHU 100 having a supplementary heat shield 132, and FIG. 2H is an enlarged representation of the slot 130 on the AHU 100 formed between a control box 120 and the supplementary heat shield 132.

In one or more embodiments, the AHU 100 may include the supplementary heat shield 132. In one or more embodiments, the supplementary heat shield 132 may be positioned between the heat elements 108 and the control box 120.

In one or more embodiments, the supplementary heat shield 132 may be mounted to the (primary) heat shield 110. The heat shield 110 may be disposed between the heat elements 108 and the control electronics.

In one or more embodiments, the supplementary heat shield 132 may be oriented on the primary heat shield 110 such that the slot 130 allows the airflow to be moved in a direction along a longitudinal axis of the housing 112.

For instance, in one or more embodiments, the primary heat shield 110 may extend across an internal cross-sectional profile of the housing 112, i.e., be perpendicularly oriented with respect to the longitudinal axis. In such embodiments, the supplementary heat shield 132 may be mounted perpendicularly on the primary heat shield 110. In other embodiments, the supplementary heat shield 132 may be inclined with respect to the primary heat shield 110.

In one or more embodiments, the supplementary heat shield 132 may be mounted downstream of the primary heat shield 110. Since the heat elements 108 may also be dispositioned downstream of the primary heat shield 110, mounting the supplementary heat shield 132 may allow the heat radiated from the heat elements 108 to be blocked and/or reflected.

In one or more embodiments, the passage/slot 130 may be configured to direct at least a portion of the airflow generated by the motor-driven fan 102 to pass between the supplementary heat shield 132 and the control electronics (i.e., between the passage/slot 130). As stated, the airflow may allow the thermal losses generated by the control electronics to be dissipated, thereby cooling the control electronics.

In one or more embodiments, the supplementary heat shield 132 and the control box 110 may be configured to form a passage (such as the slot 130) through which the airflow moves. For instance, at least a portion of the air moved by the fan 102 may move through the slot 130. The airflow may exchange heat with the control electronics (including AHU control module 122, fan motor control module 124, and/or the heat control module 126). In one or more embodiments, the control electronics may be configured to dissipate thermal losses to the airflow moving through the passage/slot 130.

In one or more embodiments, the supplementary heat shield 132 may be configured to fractionally block, reflect, absorb, and/or radiate the heat from the heat elements 108. In one or more embodiments, the supplementary heat shield 132 may also allow the heat to radiate heat from the heat elements 108 to the airflow away from the control box 120 moving downstream from the motor-driven fan 120, by convection.

In one or more embodiments, the supplementary heat shield 130 may be configured to reduce heat transfer from the heat elements 108. In such embodiments, the supplementary heat shield 132 may be configured to block the heat radiated from the heat elements 108. In one or more embodiments, the supplementary heat shield 132 may be configured to reflect the heat radiated from the heat elements 108.

In one or more embodiments, the supplementary heat shield 132 may be metallic in construction. For example, the supplementary heat shield 132 may be made of the same materials as the primary heat shield 110.

In one or more embodiments, the supplementary heat shield 132 may be planar. In other embodiments, the supplementary heat shield 132 may include a corrugated profile.

In one or more embodiments, the supplementary heat shield 132 may be disposed so that the control box 120 is blocked from the line of sight of the heat elements 108. In one or more embodiments, the supplementary heat shield 132 may be disposed (perpendicularly) along at least one edge of the primary heat shield 110.

In other embodiments, the supplementary heat shield 132 may be disposed along a perimeter of the primary heat shield 110. In such embodiments, the supplementary heat shield 132 may be configured to concentrate the heat radiated from the heat elements 108 within a region downstream of the primary heat shield 110, as the heat may be blocked from passing through, and reflected back towards the heat elements 108.

As stated, the control box 120 may include a back plate 134. The back plate 134 may be made of thermally conductive materials. In one or more embodiments, the back plate 134 may allow heat/thermal losses generated within the control box 120 by the control electronics to be dissipated out of the control box 120.

In one or more embodiments, the control electronics may be attached to the back plate 134. The thermal losses from the control electronics may be transferred to the back plate 134 through conduction. In one or more embodiments, the back plate 134 may be configured to dissipate the thermal losses from the control electronics the airflow passing through the passage/slot 130.

Further, as stated, the control box 120 may include one or more heat sinks (such as heat sink 128). The heat sink 128 may protrude into the airflow (i.e., into the passage/slot 130). In one or more embodiments, the heat sinks may be attached to the back plate 134. The heat sinks and the back plate 134 may be attached to each other in a thermally conductive manner. The heat sinks may be configured to dissipate the thermal losses from the control electronics to the airflow through the back plate 134. In one or more embodiments, the heat sinks may be disposed upstream of the supplementary heat shield 132.

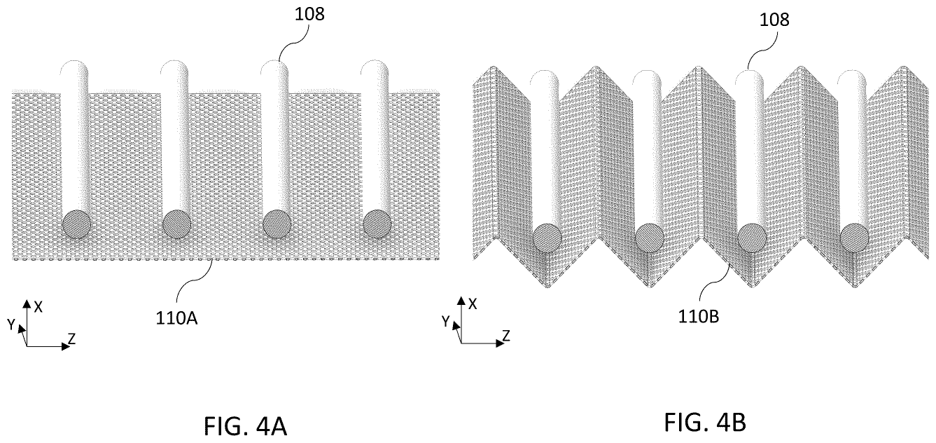

The shape of the heat shield 110 may be adapted based on the requirements for the use case. In one or more embodiments, the heat shield 110A may have a substantially planar contour as shown in FIGS. 3A and 4A. In such embodiments, the planar heat shield 110A may be defined as a planar perforated plate extending along the Y-Z plane. Further, FIG. 4A shows the heat elements 108 placed downstream of the planar heat shield 110A. The heat elements 108 may be uniformly arranged over the planar heat shield 110A.

In other embodiments, heat shield 110B may include a substantially corrugated profile, as shown in FIGS. 3B and 4B. The corrugated profile of the heat shield 110B may provide surface area that is larger than a surface area of the planar heat shield 110A of similar dimensions. In one or more embodiments, the heat elements 108 may be placed between two peaks of the corrugated heat shield 110B, at the downstream side thereof, as shown in FIG. 4B.

In one or more embodiments, the corrugated profile may also improve blocking of heat radiation due to the angled surfaces. Furthermore, the corrugations may channel the airflow to aid in a more controlled redistribution of air.

In further embodiments, the heat shield 110 may include a louvered profile. In such embodiments, multiple louvers/slats may be stacked or arranged in a parallel or overlapping manner. Gaps formed between the louvers allow for airflow passage, while the solid portions of the louvers block direct radiation. The angle of the louvers and the gaps therebetween may be adjusted to control the direction of airflow and to optimize the blocking of heat radiation.

In one or more embodiments, the heat shield 110 may include a multiple-layer profile. In such embodiments, different types of the heat shield 110 may be stacked or arranged together to form the multiple-layer profile. The multiple layer profile may provide flexibility to combine and obtain the benefits of multiple heat shields within a single AHU. In other embodiments, multiple layers of the heat shield 110 may also allow the air to be redistributed differently, based on the requirements and/or constraints of the use case.

FIGS. 5A to 5D are representations of distribution of openings defined on the heat shield 110. In one or more embodiments, the distribution of openings is formed by at least one of, perforations, slots, louvers, offset-slits, and/or mesh, but not limited thereto. In one or more embodiments, the openings may be circular, as shown in FIG.

5A. The openings may be uniformly distributed, and in a staggered arrangement. In other embodiments, the openings may be rectangular, as shown in FIG. 5B. The rectangular openings may be arranged in horizontal rows, with each row being offset with respect to adjacent rows in a staggered arrangement. In further embodiments, the openings may be formed by a mesh, as shown in FIG. 5C. The mesh may define diamond shaped openings formed by multiple wire elements arranged in an interleaving arrangement. In still further embodiments, the openings may be irregularly shaped, as shown in FIG. 5D. The irregularly shaped openings may be randomly distributed across the heat shield 110.

In one or more embodiments, a ratio of total open area to total surface area of the heat shield 110 may be between about 30% to about 65%. The open area range allows for a trade-off between airflow performance and thermal management.

In one or more embodiments, each opening in the distribution of openings may have a diameter or opening length scale of about 2 mm to about 8 mm. The number of openings may be adjusted to achieve the aforementioned total opening area. The range of opening sizes may provide a balance between allowing sufficient airflow through the heat shield 110 and effectively blocking heat radiation. In one or more embodiments, the size of the openings of the distribution may be heterogenous, such as in embodiment shown in FIG. 5D.

In one or more embodiments, the distribution of openings may be defined on the heat shield 110 to redistribute the airflow from the motor-driven fan 102 and prevent heated air back-flow from the one or more heat elements 108. The openings, due to their size, shape, and distribution, may modify the airflow profile exiting the fan 102.

Referring to FIGS. 6A to 6C, top view representations of different heat shields 110 blocking a line of sight from the heat elements 108 to the motor-driven fan 102 of the AHU 100 are shown

Referring to FIG. 6A, a top view of an AHU 100 without the heat shield 110 is shown. In FIG. 6A, the heat elements 108 are visible and positioned downstream of the fan 102 (i.e., fan outlet 107B). As shown, there is a direct line of sight from the heat elements 108 to the fan 102. The direct line of sight means that radiated heat from the heat elements 108 may directly impinge upon the fan 102 and components upstream thereof, potentially causing overheating.

Referring to FIG. 6B, a top view of an AHU 100 with the planar heat shield 110A is shown. In FIG. 6B, the heat shield 110 is disposed between the heat elements 108 and the fan 102. As shown, the heat shield 110 obstructs the direct line of sight from the heat elements 108 to the fan 102. Even though the heat shield 110 includes openings, the arrangement and size of openings and solid portions of the heat shield 110 are such that a direct, unimpeded path for heat radiation from the heat elements 108 to the fan 102 is blocked. The solid portions of the heat shield 110 interrupt the line of sight, thereby preventing direct heat radiation from reaching the fan 102.

Referring to FIG. 6C, a top view of an AHU 100 with a corrugated heat shield 110B is shown. Similar to FIG. 6B, in FIG. 6C, the corrugated heat shield 110B is disposed between the heat elements 108 and the fan 102. As shown, the corrugated heat shield 110B also obstructs the direct line of sight from the heat elements 108 to the fan 102. The corrugated profile of the heat shield 110B, with alternating peaks and troughs thereof, further enhances the blockage of line of sight. The corrugated profile of the heat shield 110B may also promote scattering and reflection of heat radiation, in addition to blocking the direct path/line-of-sight.

Thus, the heat shield 110, with distribution of openings, may provide effective thermal protection to sensitive components of the AHU 100, such as the fan 102 and electronics within the control box 120, from the heat radiated by the heat elements 108. The heat shield 110 may reduce or eliminate overheating issues, improve efficiency, and enhance reliability of the AHU 100, particularly in compact designs where components are placed in close proximity to each other. The ability of the heat shield 110 to redistribute airflow, in addition to blocking radiated heat, provides further advantages in optimizing the performance of the AHU 100.

While the subject disclosure has been described with reference to exemplary embodiments, it will be understood by those skilled in the art that various changes may be made and equivalents may be substituted for elements thereof without departing from the scope of the invention as defined by the appended claims. Modifications may be made to adapt a particular situation or material to the teachings of the invention without departing from the scope thereof. Therefore, it is intended that the invention not be limited to the particular embodiment disclosed, but that the invention includes all embodiments falling within the scope of the invention as defined by the appended claims.

In interpreting the specification, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refer to at least one of something selected from the group consisting of A, B, C . . . and N, the text should be interpreted as requiring only one element from the group, not A plus N, or B plus N, etc.

1. An air handling unit (AHU), comprising:
a motor-driven fan with an annular outlet configured to generate an airflow through a housing of the AHU;
one or more heat elements disposed downstream of the motor-driven fan, the one or more heat elements being configured to transfer heat to the airflow;
a control box positioned within the housing, the control box housing control electronics configured to control at least the one or more heat elements; and
a supplementary heat shield positioned between the one or more heat elements and the control box, wherein the supplementary heat shield and the control box form a passage through which the airflow is moved, wherein the control electronics dissipate thermal losses to the airflow moving through the passage, and wherein the supplementary heat shield is configured to reduce heat transfer from the one or more heat elements.

2. The AHU of claim 1, wherein the supplementary heat shield is mounted to a primary heat shield disposed between the one or more heat elements and the control electronics.

3. The AHU of claim 2, wherein the supplementary heat shield is oriented on the primary heat shield such that the passage allows the airflow to be moved in a direction along a longitudinal axis of the housing.

4. The AHU of claim 2, wherein the primary heat shield extends across an internal cross-sectional profile of the housing.

5. The AHU of claim 2, wherein the supplementary heat shield is mounted perpendicularly on the primary heat shield.

6. The AHU of claim 2, wherein the supplementary heat shield is mounted downstream of the primary heat shield.

7. The AHU of claim 1, wherein the passage directs at least a portion of the airflow generated by the motor-driven fan to pass between the supplementary heat shield and the control electronics.

8. The AHU of claim 1, wherein the supplementary heat shield is metallic in construction.

9. The AHU of claim 1, wherein the supplementary heat shield is planar.

10. The AHU of claim 1, wherein the control electronics comprise current modulation devices for controlling power to the one or more heat elements.

11. The AHU of claim 1, wherein the supplementary heat shield is configured to fractionally block, reflect, absorb, and/or radiate the heat from the one or more heat elements to the airflow away from the control box moving downstream from the motor-driven fan.

12. The AHU of claim 1, wherein the control box comprises a back plate configured to dissipate the thermal losses from the control electronics attached to the back plate to the airflow passing through the passage.

13. The AHU of claim 1, wherein the control box comprises one or more heat sinks protruding into the airflow, the one or more heat sinks being configured to dissipate the thermal losses from the control electronics to the airflow through the back plate.

14. The AHU of claim 13, wherein the one or more heat sinks are disposed upstream of the supplementary heat shield.

15. The AHU of claim 1, further comprising a primary heat exchanger configured to cool or heat the airflow passing through the AHU.

16. The AHU of claim 1, wherein the control box is positioned downstream of the motor-driven fan, on a side wall of the housing.

17. An air handling unit (AHU), comprising:
a motor-driven fan with an annular outlet configured to generate an airflow through a housing of the AHU;
one or more heat elements disposed downstream of the motor-driven fan, the one or more heat elements being configured to transfer heat to the airflow;
a control box positioned within the housing, the control box housing control electronics configured to control at least the one or more heat elements; and
a supplementary heat shield attached to the control box, wherein the supplementary heat shield is configured to dissipate heat from the control electronics to the airflow, and wherein the supplementary heat shield is configured to reduce heat transfer from the one or more heat elements.
